(19) United States
(12) Patent Application Publication
(10) Pub. No.: US 2026/0231803 A1
(43) Pub. Date: Aug. 6, 2026

(54) APPARATUS FOR PREVENTING OXIDATION OF ELECTRONIC PART

(71) Applicant: SHIBUYA CORPORATION, Kanazawa-shi (JP)

(72) Inventor: Masato KITAGAWA, Kanazawa-shi (JP)

(21) Appl. No.: 19/464,787

(22) Filed: Jan. 30, 2026

(30) Foreign Application Priority Data
Jan. 31, 2025 (JP) 2025-015344

(51) Int. Cl. H10W 72/00

(52) U.S. Cl. CPC H10W 72/01271; H10W 72/011

(57) ABSTRACT

An apparatus for preventing oxidation of an electronic part, irradiating a bump B of an electronic part with plasma to remove an oxide film. The apparatus includes a holding head including a spray port adjacent to the electronic part, and a moving unit configured to move the holding head. An irradiation portion of a plasma irradiation unit is provided between a reception position and a transfer position and a facing surface from the irradiation portion to the transfer position is provided. The moving unit moves the holding head in a state where the bump of the electronic part held by the holding head is brought close to the facing surface. Inert gas is continuously sprayed from the spray port to form an inert gas atmosphere between the electronic part and the facing surface.

### BACKGROUND OF THE INVENTION

### Field of the Invention

The present invention relates to an apparatus for preventing oxidation of an electronic part, and more specifically, to an apparatus for preventing oxidation of an electronic part, including a plasma irradiation unit that irradiates bumps formed on a bonding surface of the electronic part with plasma to remove oxide films.

### Description of the Related Art

There is known a bonding apparatus that includes a bonding stage supporting a substrate such as a semiconductor wafer, and a bonding head holding an electronic part such as a semiconductor chip, and bonds the electronic part to the substrate (Japanese Laid-Open Patent Application Nos. 2022-174463 and 2024-176705).

To bond the electronic part and the substrate, it is necessary to melt bumps made of solder or the like formed on bonding surfaces by laser light or the like. At this time, when an oxide film is formed on a surface of each bump, bonding is inhibited.

Therefore, there is known an apparatus for preventing oxidation of an electronic part, including a plasma irradiation unit that irradiates the bumps with plasma to remove the oxide films (Japanese Laid-Open Patent Application No. 2024-150426).

In Japanese Laid-Open Patent Application No. 2024-150426, to prevent the oxide films from being reformed on the bumps after the oxide films are removed, bonding of the electronic part and the substrate is performed in an inert gas atmosphere of nitrogen gas or the like.

However, a bonding system disclosed in Japanese Laid-Open Patent Application No. 2024-150426 has an issue that, in order to maintain the plasma irradiation unit and the bonding apparatus in the inert gas atmosphere, a chamber for storing the plasma irradiation unit and the bonding apparatus is necessary, which causes upsizing of the apparatus, and in order to fill the chamber with inert gas, a large amount of inert gas is necessary.

In consideration of such an issue, the present invention is to provide an apparatus for preventing oxidation of an electronic part that can reduce a use amount of inert gas without being upsized.

### SUMMARY OF THE INVENTION

An apparatus for preventing oxidation of an electronic part according to one aspect of the invention includes a plasma irradiation unit configured to irradiate a bump formed on a bonding surface of the electronic part with plasma to remove an oxide film formed on the bump, and the apparatus includes: a holding head including a holding surface configured to hold the electronic part on a surface opposite to a bonding surface, and a spray port formed at a position adjacent to the electronic part held by the holding surface; a gas supply unit configured to spray inert gas from the spray port; and a moving unit configured to move the holding head from a reception position to a transfer position of the electronic part, characterized in that an irradiation portion of the plasma irradiation unit is provided between the reception position and the transfer position, and a facing surface facing an entire bonding surface of the electronic part held by the moving holding head is provided continuously from the irradiation portion to the transfer position, the holding head includes the spray port at least on a front side in a moving direction toward the transfer position, the moving unit moves the holding head holding the electronic part at the reception position, from the irradiation portion to the transfer position in a state where the bump of the held electronic part and the facing surface are brought close to each other, and the gas supply unit continuously sprays inert gas from the spray port during a period from a time when plasma is emitted from the irradiation portion until the electronic part is moved to the transfer position.

The apparatus for preventing oxidation of the electronic part according to the invention can remove the oxide film on the bump by the plasma irradiation unit while the electronic part is moved from the reception position to, for example, the transfer position set in the bonding apparatus.

At this time, the electronic part is moved in a state where the bump of the electronic part is brought close to the facing surface while the inert gas is sprayed from the spray port of the holding head moved by the moving unit. This makes it possible to form a high-concentration inert gas atmosphere between the holding head and the facing surface by a small spray amount.

As a result, it is possible to reduce the use amount of inert gas without upsizing the apparatus, and to move the electronic part to the transfer position while preventing the oxide film from being reformed on the bump after plasma irradiation.

### BRIEF DESCRIPTION OF THE DRAWINGS

FIG. 1 is a configuration diagram of a bonding system according to a present embodiment;

FIG. 2 is a configuration diagram of a bonding apparatus;

FIG. 3 is a configuration diagram of a transfer apparatus serving as an apparatus for preventing oxidation of an electronic part;

FIG. 4 is a bottom view of a holding head;

FIG. 5 is a plan view of a plasma irradiation unit and a relay stage; and

FIG. 6 is a bottom view of the holding head having a surrounding spray port.

### DETAILED DESCRIPTION OF THE INVENTION

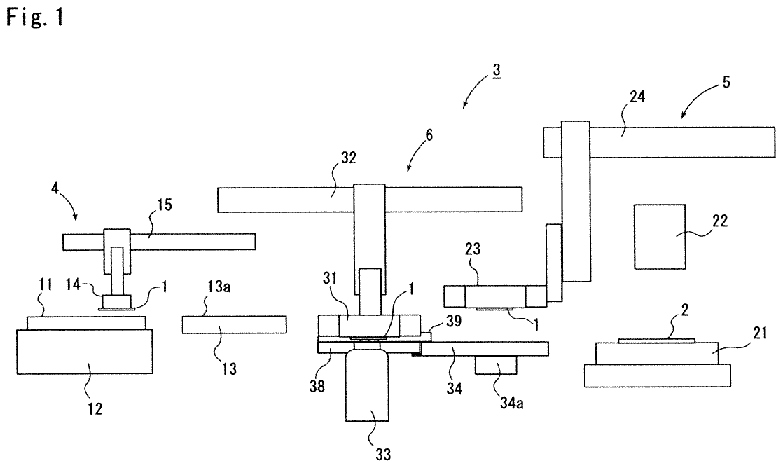

An illustrated embodiment is described below. FIG. 1 illustrates a bonding system 3 that bonds an electronic part 1 such as a semiconductor chip to a substrate 2 such as a semiconductor wafer.

The bonding system 3 includes a supply apparatus 4 that supplies the electronic part 1, a bonding apparatus 5 that bonds the electronic part 1 to the substrate 2, and a transfer apparatus 6 that moves the electronic part 1 from the supply apparatus 4 to the bonding apparatus 5. These apparatuses are controlled by an unillustrated control unit. Further, the transfer apparatus 6 configures an apparatus for preventing oxidation of an electronic part according to the present invention.

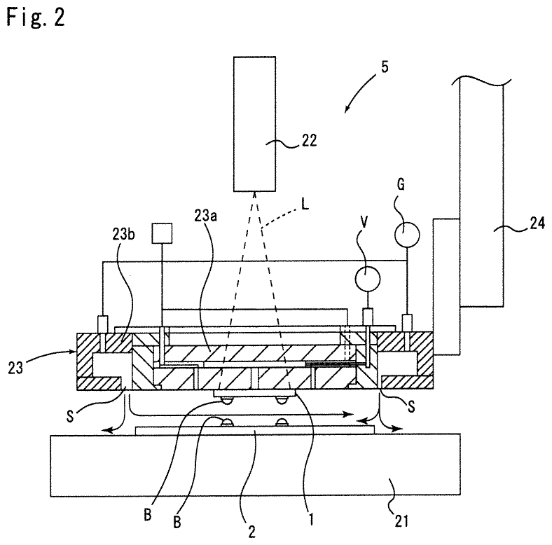

The electronic part 1 has a substantially square shape in a plan view, and a lower surface illustrated in FIG. 1 is a bonding surface bonded to the substrate 2. A plurality of electrodes are provided on the bonding surface, and a bump B made of solder is provided on each of the electrodes (see FIG. 2).

A plurality of electronic parts 1 may be bonded to an upper surface of the substrate 2. At a position on the upper surface of the substrate 2 where the electronic part 1 is to be bonded, electrodes are provided in the same arrangement as arrangement of the electrodes of the electronic part 1, and a bump B made of solder is provided on each of the electrodes (see FIG. 2).

In the bonding system 3 according to the present embodiment, the transfer apparatus 6 transfers the electronic part 1 supplied from the supply apparatus 4 to the bonding apparatus 5, and the bonding apparatus 5 bonds the electronic part 1 to the substrate 2.

The supply apparatus 4 comprises a supply table 12 on which a tray 11 storing the electronic part 1 is placed, a transfer table 13 on which one electronic part 1 is placed, a supply head 14 that sucks and holds the electronic part 1, and a moving unit 15 that moves the supply head 14.

A plurality of electronic parts 1 are stored in the tray 11 in a state where the bonding surfaces are directed downward. Further, one electronic part 1 is placed on a supply surface 13a formed on an upper surface of the transfer table 13 such that the bonding surface is directed downward.

The supply head 14 is configured to suck and hold an upper surface of the electronic part 1 that is a surface on a side opposite to the bonding surface, and the moving unit 15 moves the supply head 14 in a horizontal direction and a vertical direction.

With such a configuration, the moving unit 15 moves the supply head 14, takes out one electronic part 1 from the tray 11 placed on the supply table 12, and places the one electronic part 1 on the transfer table 13.

As illustrated in FIG. 2, the bonding apparatus 5 includes a bonding stage 21 supporting the substrate 2, a laser light irradiation unit 22 emitting laser light L, a bonding head 23 holding the electronic part 1, and a moving unit 24 moving the bonding head 23. The bonding apparatus 5 described in the present embodiment is disclosed in Japanese Laid-Open Patent Application No. 2022-174463. Therefore, detailed description of the bonding apparatus 5 is omitted.

The substrate 2 is placed on a substantially center of the bonding stage 21, and the bumps B are positioned on the upper surface of the placed substrate 2.

As disclosed in Japanese Laid-Open Patent Application No. 2024-176705, the bonding stage 21 may be a bonding stage including a stage-side gas supply unit covering a periphery of the substrate 2 with an inert gas atmosphere.

The laser light irradiation unit 22 is provided above the bonding stage 21. When the bonding head 23 holding the electronic part 1 is positioned below the laser light irradiation unit 22, the laser light irradiation unit 22 emits the laser light L to melt the bumps on the electronic part 1 and the substrate 2, thereby bonding the electronic part 1 and the substrate 2.

The bonding head 23 includes a holding portion 23a sucking and holding the electronic part 1, and is connected to a gas supply unit G forming an inert gas atmosphere around the held electronic part 1.

A negative pressure supply unit V supplies negative pressure to a lower surface of the holding portion 23a, and the surface (upper surface) of the electronic part 1 opposite to the bonding surface is sucked and held in a state where the bonding surface is directed downward.

A spray portion 23b is provided so as to surround the holding portion 23a, and a slit S is formed on a lower surface of the spray portion 23b so as to surround the electronic part 1.

Inert gas supplied from the gas supply unit G is sprayed from the slit S to form the inert gas atmosphere around the electronic part 1 held by the holding portion 23a.

The moving unit 24 is configured to move the bonding head 23 in the horizontal direction and the up-down direction. In the present embodiment, the moving unit 24 moves the bonding head 23 between a holding position (see FIG. 1) where the electronic part 1 on a relay stage 34 of the transfer apparatus 6 is held and a bonding position (see FIG. 2) where the held electronic part 1 is bonded to the substrate 2 on the bonding stage 21.

The transfer apparatus 6 includes a holding head 31 holding the electronic part 1, a moving unit 32 moving the holding head 31, a plasma irradiation unit 33 irradiating the bonding surface of the electronic part 1 with plasma, and the relay stage 34 transferring the electronic part 1 to the bonding head 23 of the bonding apparatus 5.

The holding head 31 is movable in the horizontal direction and the up-down direction by the moving unit 32, and is moved between the transfer table 13 of the supply apparatus 4 and the relay stage 34.

To move the electronic part 1 from the transfer table 13 to the relay stage 34, the holding head 31 is moved from a left side to a right side illustrated in FIG. 1. Therefore, an illustrated right side of the electronic part 1 held by the holding head 31 is a front side in a moving direction.

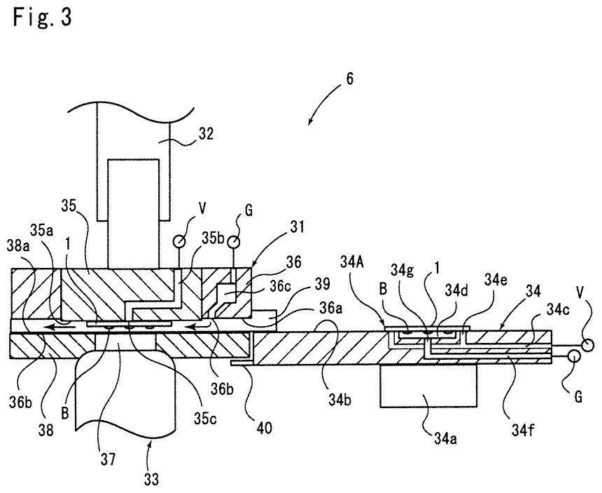

As illustrated in FIG. 3, the holding head 31 includes a holding portion 35 holding the electronic part 1, and an expansion portion 36 spraying inert gas. The negative pressure supply unit V for sucking and holding the electronic part 1 is connected to the holding portion 35. The gas supply unit G for spraying the inert gas such as nitrogen to a periphery of the electronic part 1 is connected to the expansion portion 36.

By spraying the inert gas in such a manner, a low-oxygen concentration atmosphere is maintained around the electronic part 1 to prevent oxide films from being formed on the bumps B.

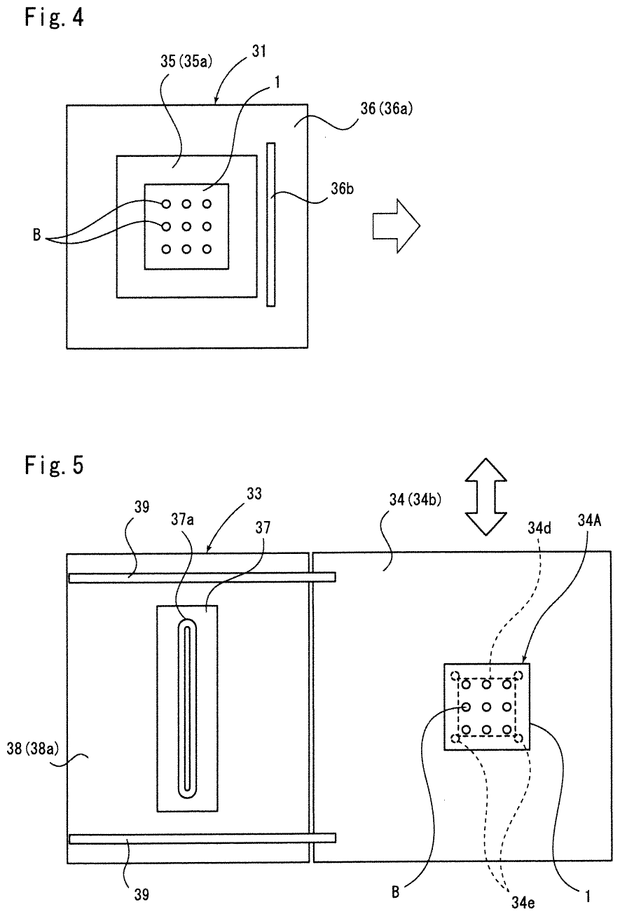

As illustrated in FIG. 4, a holding surface 35a that has a substantially square shape and has an area slightly greater than an area of the bonding surface of the electronic part 1 is formed on a lower surface of the holding portion 35. The holding surface 35a tightly adheres to the upper surface of the electronic part 1.

A negative pressure passage 35b connected to a suction hole 35c that opens in the lower surface is provided inside the holding portion 35. When the negative pressure supply unit V supplies negative pressure to the negative pressure passage 35b, the electronic part 1 can be sucked to and held by the holding surface 35a.

The expansion portion 36 is provided so as to surround the holding portion 35. An expansion surface 36a provided on a lower surface of the expansion portion 36 is formed to be continuous with the holding surface 35a of the holding portion 35 without a gap at the same height or through a small level difference.

A gas passage 36c provided such that a spray port 36b opens in the expansion surface 36a is provided inside the expansion portion 36, and the gas supply unit G is connected to the gas passage 36c.

As illustrated in FIG. 4, the spray port 36b is provided at a position adjacent to an illustrated right side of the holding surface 35a holding the electronic part 1, and a length of the spray port 36b is set longer than a width of the holding surface 35a.

The holding head 31 holding the electronic part 1 is moved from an illustrated left side to an illustrated right side, and therefore, the spray port 36b is provided on a front side of the held electronic part 1 in a moving direction of the holding head 31. The length of the spray port 36b exceeds a width of the held electronic part 1.

Therefore, the inert gas sprayed from the spray port 36b stagnates below the holding head 31 in a state where movement of the holding head 31 is stopped. When the holding head 31 is moved to the illustrated right side where the spray port 36b is provided, the sprayed inert gas flows rearward to position the electronic part 1 inside the inert gas atmosphere.

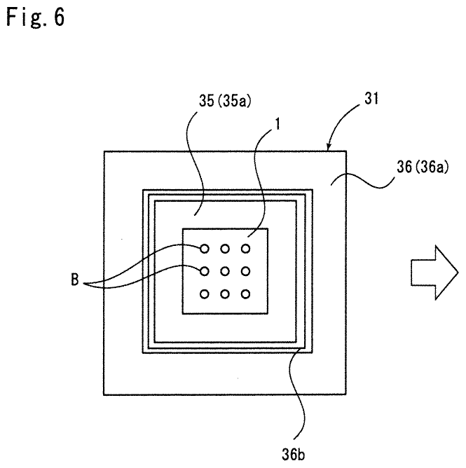

Note that it is necessary to form the spray port 36b at least at an adjacent position on the front side of the electronic part 1 held to the holding surface 35a in the moving direction; however, as with the slit S provided in the bonding head 23 illustrated in FIG. 2 and the spray port 36b illustrated in FIG. 6, the spray port 36b may be provided so as to surround the holding surface 35a, and spray the inert gas from four sides to the held electronic part 1.

In a case where the surrounding spray port 36b is formed, the electronic part 1 can be positioned inside the inert gas atmosphere even in the state where movement of the holding head 31 is stopped. At this time, by making an opening area of the spray port 36b on the front side in the moving direction greater than an opening area of each of the other sides, it is possible to relatively increase a spray amount of the inert gas. Although the spray port 36b is increased in opening area by surrounding the holding surface 35a, it is possible to sufficiently inhibit inflow of surrounding gas flowing from the front side in the moving direction during movement while reducing a supply amount of inert gas, and to inhibit inflow of the surrounding gas from the sides and the rear side during stoppage.

The plasma irradiation unit 33 is provided in a middle of the moving path of the holding head 31 and the electronic part 1 held by the holding head 31. More specifically, the plasma irradiation unit 33 is provided between a reception position set on the transfer table 13 of the supply apparatus 4 and a transfer position set on the relay stage 34.

The plasma irradiation unit 33 is an existing well-known unit, and irradiates the bonding surface of the electronic part 1 with plasma to remove the oxide films formed on outer surfaces of the bumps B.

As illustrated in FIG. 3, the plasma irradiation unit 33 according to the present embodiment includes an irradiation portion 37 emitting plasma upward, and a flange portion 38 provided so as to surround the irradiation portion 37.

As illustrated in FIG. 5, the irradiation portion 37 includes an irradiation window 37a having a slit shape. The irradiation window 37a is formed in a direction orthogonal to the moving direction of the holding head 31, and a length thereof is set longer than the width of the holding surface 35a of the holding head 31 and the width of the electronic part 1.

The flange portion 38 is provided so as to surround the irradiation portion 37, and includes a flange surface 38a that is a flat peripheral surface formed on the front side and the rear side of the irradiation portion 37 in the moving direction of the holding head 31.

The flange surface 38a is provided at the same height as an upper surface of the irradiation window 37a of the irradiation portion 37, and configures a facing surface facing the entire bonding surface of the electronic part 1 held by the holding head 31 moving above the flange surface 38a.

The flange surface 38a according to the present embodiment is formed such that, when the holding head 31 positions the electronic part 1 above the irradiation window 37a, a sufficient space is secured on each of the front side and the rear side of the electronic part 1 in the moving direction. Note that the flange portion 38 may be provided only on the front side of the irradiation portion 37 in the moving direction of the holding head 31, but providing the flange portion 38 on the rear side in the moving direction makes it possible to stabilize concentration of the inert gas filled in a space between the holding surface 35a of the holding head 31 and the facing surface configured by the flange surface 38a of the flange portion 38.

As illustrated in FIG. 5, paired covers 39 facing each other are provided on the flange portion 38 along the moving path of the holding head 31, and the holding head 31 holding the electronic part 1 moves in a space between the covers 39.

Heights of the covers 39 are set so as to be higher than a gap between the holding surface 35a of the holding head 31 and the flange surface 38a of the flange portion 38 when the holding head 31 moves the electronic part 1 to the relay stage 34. The covers 39 are brought close to the expansion portion 36 configuring a surrounding portion of the moving holding head 31 to cover a gap between the expansion surface 36a and the flange surface 38a on sides in the moving direction, thereby preventing outflow of the inert gas.

Ends of the covers 39 on the illustrated right side protrude outward from an end of the flange portion 38, and reach above the relay stage 34.

The relay stage 34 is provided to be movable in the horizontal direction by the moving unit 34a. In FIG. 3, the relay stage 34 reciprocates in a depth direction of a paper surface (up-down direction in FIG. 5) orthogonal to the moving direction of the moving unit 32.

The relay stage 34 moves between a position adjacent to the flange portion 38 of the plasma irradiation unit 33 and a standby position where the bonding head 23 of the bonding apparatus 5 stands by. FIG. 5 illustrates a state where the relay stage 34 is at the position adjacent to the flange portion 38.

A flat placement surface 34b is provided on an upper surface of the relay stage 34. The placement surface 34b is formed as a flush surface at the same height as the flange surface 38a of the flange portion 38. The placement surface 34b and the flange surface 38a configure a facing surface facing the entire bonding surface of the electronic part 1 held by the holding head 31.

The placement surface 34b according to the present embodiment is formed such that, when the holding head 31 positions the electronic part 1 on a placement portion 34A serving as the transfer position set on the placement surface 34b, a sufficient space is secured on each of the front side and the rear side of the electronic part 1 in the moving direction.

Further, when the relay stage 34 is at the position adjacent to the flange portion 38, the flange portion 38 and the relay stage 34 are brought close to each other as much as possible. A cover 40 covering a gap that may be formed between the flange portion 38 and the relay stage 34 is provided on a lower surface of the relay stage 34 to inhibit outflow of the inert gas from the gap.

In the above-described manner, the flange surface 38a and the placement surface 34b configure the facing surface continuous from the irradiation portion 37 to the transfer position on the relay stage 34.

As illustrated in FIG. 3, the placement portion 34A includes a suction passage 34c for sucking the electronic part 1, and a concave portion 34d for maintaining the bumps B of the electronic part 1 in the inert gas atmosphere.

Further, the placement portion 34A includes a plurality of suction holes 34e at positions avoiding the bumps B of the electronic part 1, and the suction holes 34e are connected to the negative pressure supply unit V through the suction passage 34c.

With such a configuration, when the electronic part 1 is placed on the placement portion 34A, the electronic part 1 is sucked to the suction holes 34e by negative pressure.

The concave portion 34d is formed in a range where the bumps B of the electronic part 1 are provided. When the electronic part 1 is placed on the placement portion 34A, the bumps B are housed in a space formed in the concave portion 34d.

The inert gas is supplied from the gas supply unit G to the concave portion 34d through a gas passage 34f, and is sprayed from a spray port 34g opening inside the concave portion 34d.

With such a configuration, when the electronic part 1 is placed on the placement portion 34A, the concave portion 34d is sealed from outside by the electronic part 1 tightly adhering to the placement surface 34b. Thus, the inside of the concave portion 34d is maintained in the inert gas atmosphere.

Operation of the bonding system 3 having the above-described configuration is described below. Note that operation of the bonding apparatus 5 is disclosed in Japanese Laid-Open Patent Application No. 2022-174463, and therefore, detailed description thereof is omitted.

First, the tray 11 in which a plurality of electronic parts 1 are stored is supplied to the supply table 12 of the supply apparatus 4. At this time, the bumps B are formed on the bonding surface of each of the electronic parts 1, and the electronic parts 1 are stored in the tray 11 in a state where the bonding surfaces are directed downward.

At this time, oxide films are formed on surfaces of the bumps B formed on the electronic parts 1 supplied to the supply apparatus 4 because the electronic parts 1 are handled under an environment containing oxygen.

The supply apparatus 4 moves the supply head 14 by the moving unit 15, sucks and holds one of the electronic parts 1 stored in the tray 11, and places the electronic part 1 on the transfer table 13.

Thereafter, in the transfer apparatus 6, the moving unit 32 moves the holding head 31, and the holding portion 35 of the holding head 31 sucks and holds the electronic part 1 placed on the transfer table 13.

After the holding head 31 sucks and holds the electronic part 1, the moving unit 32 slightly lifts the holding head 31, and then moves the holding head 31 in the horizontal direction from the illustrated left side to the illustrated right side toward the plasma irradiation unit 33.

Further, after the electronic part 1 is sucked and held by the holding head 31, the gas supply unit G sprays the inert gas from the spray port 36b provided in the expansion portion 36, thereby forming the inert gas atmosphere around the electronic part 1.

Subsequently, after the holding head 31 is positioned between the transfer table 13 and the plasma irradiation unit 33, the moving unit 32 lowers the holding head 31.

At this time, the moving unit 32 lowers the holding head 31 such that a gap of about 0.5 mm to about 1 mm is formed between the holding surface 35a of the holding head 31 and the flange surface 38a of the flange portion 38 of the plasma irradiation unit 33.

Thereafter, the moving unit 32 continuously moves the holding head 31 until the holding head 31 reaches the relay stage 34 without changing the height of the holding head 31. As a result, during movement of the holding head 31, a state where the bumps B of the electronic part 1 held by the holding head 31 and the facing surface configured by the flange surface 38a and the placement surface 34b of the relay stage 34 are close to each other is maintained.

When the holding head 31 reaches the flange portion 38 of the plasma irradiation unit 33, the gap of about 0.5 mm to about 1 mm is formed between the holding surface 35 a of the holding head 31 and the flange surface 38a as described above.

The inert gas is sprayed from the spray port 36b of the holding head 31. The inert gas flows between both the holding surface 35a of the holding head 31 and the bonding surface of the electronic part 1, and the flange surface 38a to form the high-concentration inert gas atmosphere around the bumps B of the electronic part 1.

The high-concentration inert gas atmosphere can be formed by a small amount of inert gas sprayed from the spray port 36b of the holding head 31, and accordingly, a use amount of inert gas can be reduced.

Further, the covers 39 provided on the flange portion 38 prevent the inert gas from flowing out from the gap between the expansion surface 36a of the holding head 31 and the flange surface 38a.

Since the holding head 31 continuously moves in the horizontal direction without changing the height, the electronic part 1 held by the holding head 31 passes above the irradiation portion 37 of the plasma irradiation unit 33, and the oxide films formed on the surfaces of the bumps B are removed by the irradiated plasma.

Since the flange surface 38a is provided around the irradiation portion 37, the state where the bumps B of the electronic part 1 and the flange surface 38a are close to each other is maintained before and after the electronic part 1 passes above the irradiation portion 37.

As a result, plasma is emitted in the inert gas atmosphere, the high-concentration inert gas atmosphere is formed around the bumps B from which the oxide films are removed, continuously from the time when the plasma is emitted, and reformation of the oxide films on the bumps B is prevented as much as possible.

When the holding head 31 further moves in the horizontal direction without changing the height, the holding head 31 is transferred from the flange surface 38a to the placement surface 34b of the relay stage 34.

The placement surface 34b of the relay stage 34 is also set at the same height as the flange surface 38a of the flange portion 38 and maintains a flush surface, and continuously configures the facing surface. Therefore, the bumps B of the electronic part 1 held by the holding head 31 also maintain the state of being close to the placement surface 34b.

As a result, the high-concentration inert gas atmosphere can be maintained between both the holding surface 35a of the holding head 31 and the bonding surface of the electronic part 1, and the placement surface 34b, and reformation of the oxide films on the bumps B is still prevented.

In this case, an area of the holding surface 35a is set greater than an area of the bonding surface of the electronic part 1. Further, the flange surface 38a and the placement surface 34b configuring the facing surface face the entire bonding surface of the moving electronic part 1. Thus, the inert gas atmosphere around the bumps B can be reliably maintained.

When the holding head 31 passes through a boundary between the flange portion 38 and the relay stage 34, the inert gas attempts to flow out downward from a gap therebetween; however, the cover 40 provided on the lower surface of the relay stage 34 can prevent outflow of the inert gas.

After the holding head 31 moves to the placement portion 34A set on the placement surface 34b of the relay stage 34, the moving unit 32 lowers the holding head 31 to place the electronic part 1 on the placement portion 34A, and then, the electronic part 1 is sucked to and held by the placement surface 34b of the relay stage 34.

The holding head 31 having placed the electronic part 1 is lifted by the moving unit 32, and then, is moved to the supply apparatus 4. At this time, spraying of the inert gas from the spray port 36b can be stopped.

On the other hand, when the bonding surface of the electronic part 1 is sucked to the placement portion 34A of the relay stage 34, the bumps B of the bonding surface are housed inside the concave portion 34d formed in the placement portion 34A.

Since the gas supply unit G constantly supplies the inert gas to the inside of the concave portion 34d, the inert gas atmosphere around the bumps B is continuously maintained without interruption.

As a result, during a period from the time when the plasma is emitted from the irradiation portion 37 of the plasma irradiation unit 33 until the electronic part 1 is moved to the placement portion 34A of the relay stage 34 that is the transfer position and is then stored in the concave portion 34d, the inert gas is continuously sprayed from the spray port 36b, which maintains the inert gas atmosphere and prevents reformation of the oxide films on the bumps B.

After the electronic part 1 is placed on the placement surface 34b of the relay stage 34 in the above-described manner, the relay stage 34 moves to the bonding apparatus 5.

During the period, the inert gas is supplied to the concave portion 34d. Therefore, a state where reformation of the oxide films on the bumps B of the electronic part 1 is prevented is maintained.

Thereafter, when the relay stage 34 moves to the standby position where the bonding head 23 of the bonding apparatus 5 stands by, the bonding head 23 is lowered by the moving unit 24, and sucks and holds the electronic part 1.

At this time, the inert gas is sprayed from the spray portion 23b surrounding the holding portion 23a of the bonding head 23, and the inert gas atmosphere is continuously formed around the bumps B of the sucked and held electronic part 1 without interruption.

Thereafter, the bonding head 23 moves the electronic part 1, and places the electronic part 1 on the substrate 2 on the bonding stage 21. In this state, the laser light irradiation unit 22 emits the laser light L to melt solder configuring the bumps B, and the electronic part 1 is bonded to the substrate 2.

As described above, the bonding system 3 according to the present embodiment can remove the oxide films formed on the bumps B of the electronic part 1 by the plasma irradiation unit 33 while the transfer apparatus 6 transfers the electronic part 1 to the bonding apparatus 5.

In addition, since the transfer apparatus 6 continuously forms the inert gas atmosphere around the electronic part 1 held by the holding head 31, the transfer apparatus 6 can transfer the electronic part 1 to the bonding apparatus 5 while preventing the oxide films from being reformed on the bumps B.

At this time, the inert gas is supplied while the holding head 31 is moved in a state where the bumps B of the electronic part 1 held by the holding head 31 and the facing surface configured by the flange surface 38a of the flange portion 38 of the plasma irradiation unit 33 and the placement surface 34b of the relay stage 34 are brought close to each other. Accordingly, the high-concentration inert gas atmosphere can be formed by a small amount of inert gas.

In the above-described embodiment, the relay stage 34 is provided adjacently to the flange portion 38 of the plasma irradiation unit 33, and the electronic part 1 is transferred to the bonding stage 21 through the relay stage 34; however, the electronic part 1 may be directly transferred to the bonding apparatus 5 by the holding head 31.

In this case, the facing surface configured by the flange surface 38a of the flange portion 38 of the plasma irradiation unit 33 is provided continuously from the irradiation portion 37 to the transfer position for the bonding head 23, which makes it possible to form the high-concentration inert gas atmosphere around the bumps B of the electronic part 1, in a manner similar to the above-described embodiment.

Further, as illustrated in FIG. 6, in a case where the spray port 36b is formed so as to surround the held electronic part 1, the electronic part 1 can be irradiated with the plasma in a state of being stopped once or being slowly moved above the irradiation portion 37.

This makes it possible to irradiate the electronic part 1 with the plasma for an appropriate time to obtain a necessary irradiation amount, for example, in a case where the number of bumps of the electronic part 1 is large.

### REFERENCE SIGNS LIST

1 Electronic part
2 Substrate
3 Bonding system
4 Supply apparatus
5 Bonding apparatus
6 Transfer apparatus (apparatus for preventing oxidation of electronic part)
13 Transfer table (reception position)
31 Holding head
32 Moving unit
33 Plasma irradiation unit
34 Relay stage
34A Placement portion (transfer position)
34b Placement surface (facing surface)
35 Holding portion
36 Expansion portion
36b Spray port
37 Irradiation portion
38 Flange portion
38a Flange surface (facing surface)
B Bump
G Gas supply unit
V Negative pressure supply unit

1. An apparatus for preventing oxidation of an electronic part, the apparatus including a plasma irradiation unit configured to irradiate a bump formed on a bonding surface of the electronic part with plasma to remove an oxide film formed on the bump, the apparatus comprising:
a holding head including a holding surface configured to hold the electronic part on a surface opposite to a bonding surface, and a spray port formed at a position adjacent to the electronic part held by the holding surface;
a gas supply unit configured to spray inert gas from the spray port; and
a moving unit configured to move the holding head from a reception position to a transfer position of the electronic part, wherein
an irradiation portion of the plasma irradiation unit is provided between the reception position and the transfer position, and a facing surface facing an entire bonding surface of the electronic part held by the moving holding head is provided continuously from the irradiation portion to the transfer position,
the holding head includes the spray port at least on a front side in a moving direction toward the transfer position,
the moving unit moves the holding head holding the electronic part at the reception position, from the irradiation portion to the transfer position in a state where the bump of the held electronic part and the facing surface are brought close to each other, and
the gas supply unit continuously sprays inert gas from the spray port during a period from a time when plasma is emitted from the irradiation portion until the electronic part is moved to the transfer position.

2. The apparatus for preventing oxidation of the electronic part according to claim 1, wherein the spray port of the holding head is provided to surround the electronic part held by the holding surface.

3. The apparatus for preventing oxidation of the electronic part according to claim 1, wherein a cover covering a gap between the holding surface of the holding head and the facing surface is provided along a moving path of the holding head.

4. The apparatus for preventing oxidation of the electronic part according to claim 1, wherein
a placement portion on which the electronic part is placed, is provided at the transfer position, and
a concave portion storing the bump formed on the bonding surface of the electronic part is provided on the placement portion, and a gas supply unit configured to supply inert gas to the concave portion is provided.
